(19) United States
(12) Patent Application Publication
(10) Pub. No.: US 2022/0320953 A1
(43) Pub. Date: Oct. 6, 2022

(54) MOTOR UNIT

(71) Applicant: NIDEC CORPORATION, Kyoto (JP)

(72) Inventors: Ryohei KASAHARA, Kyoto (JP); Takayuki MAKINO, Kyoto (JP); Masato AONO, Kyoto (JP); Yoshiyuki Aono, Kyoto (JP)

(21) Appl. No.: 17/704,007

(22) Filed: Mar. 25, 2022

(30) Foreign Application Priority Data
Mar. 30, 2021 (JP) 2021-057542

(51) Int. Cl. H02K 7/00; H02K 7/08; H02K 7/116; H02K 5/22; H02K 5/16

(52) U.S. Cl. CPC H02K 7/003; H02K 7/08; H02K 7/116; H02K 5/225; H02K 5/16

(57) ABSTRACT

A motor unit includes a shaft and an electrical discharging device. The shaft includes a helical gear. The electrical discharging device includes a contact member, a biasing member, and a case. The biasing member biases the contact member toward an end face of an end part of the shaft in a direction parallel to the axial direction of the shaft. The contact member has conductivity. The contact member is brought into contact with the end face by the biasing of the biasing member. The maximum stroke amount of the contact member in the axial direction is larger than the movement width of the shaft in the axial direction during rotation.

### CROSS-REFERENCE TO RELATED APPLICATIONS

The present invention claims priority under 35 U.S.C. § 119 to Japanese Patent Application No. 2021-057542 filed on Mar. 30, 2021, the entire content of which is incorporated herein by reference.

### FIELD OF THE INVENTION

The present invention relates to a motor unit.

### BACKGROUND

In a motor unit, a phenomenon in which electric charge is accumulated in a shaft occurs due to an electromagnetic induction voltage generated by magnetic imbalance, static electricity generated by rotational friction, and the like. A motor having a device for releasing electric charge accumulated in a shaft is known. For example, there is known a shaft grounding device of a vehicle that includes a ground member in contact with a rotating shaft and grounds the rotating shaft through the ground member, in which the ground member includes a sliding contact part that comes into sliding contact with and conducts with an end face of the rotating shaft.

The conventional electrical discharging device abuts on and is brought into contact with the end face of the shaft. The electrical discharging device is pressed against the end face of the shaft by biasing means such as a spring. On the other hand, helical gears are often used as gears of a drive device. While there is no problem when the shaft rotates only in one direction, when the shaft rotates in both directions or when the direction in which the force of the helical gear is received is changed due to power running or regeneration, the shaft moves in the axial direction. In this case, in the conventional electrical discharging device, it is necessary to increase the depth of the recess of the shaft (rotating shaft). However, when the depth of the recess is increased, the electrical discharging device cannot be brought into contact with the end part (end face), and it is difficult to ensure sufficient electrical discharging performance.

### SUMMARY

An exemplary motor unit of the present invention includes a shaft and an electrical discharging device. The shaft includes a helical gear. The shaft rotates about a rotation axis. The electrical discharging device includes a contact member, a biasing member, and a case. At least one electrical discharging device is provided. The case accommodates the contact member and the biasing member. The biasing member biases the contact member toward an end face of an end part of the shaft in a direction parallel to an axial direction of the shaft. The contact member has conductivity. The contact member is brought into contact with the end face by biasing of the biasing member. The maximum stroke amount of the contact member in the axial direction is larger than the movement width of the shaft in the axial direction.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a conceptual diagram illustrating an example of a motor unit according to an embodiment;

FIG. 2 is a diagram illustrating an example of a shaft according to the embodiment;

FIG. 3 is a diagram illustrating an example of an electrical discharging device and the shaft according to the embodiment;

FIG. 4 is a diagram illustrating an example of the electrical discharging device according to the embodiment;

FIG. 5 is a diagram illustrating an example of the electrical discharging device according to the embodiment;

FIG. 6 is a diagram illustrating an example of a motor unit according to a first modification;

FIG. 7 is a diagram illustrating an example of a motor unit according to a second modification;

FIG. 8 is a diagram illustrating an example of a motor unit according to a fourth modification;

FIG. 9 is a diagram illustrating an example of a motor unit according to a fifth modification; and

FIG. 10 is a diagram illustrating an example of a motor unit according to a sixth modification.

### DETAILED DESCRIPTION

Hereinafter, a motor unit 1 according to an embodiment of the present invention will be described with reference to the drawings. Note that the scope of the present invention is not limited to the embodiments described below, but includes any modification thereof within the scope of the technical idea of the present invention.

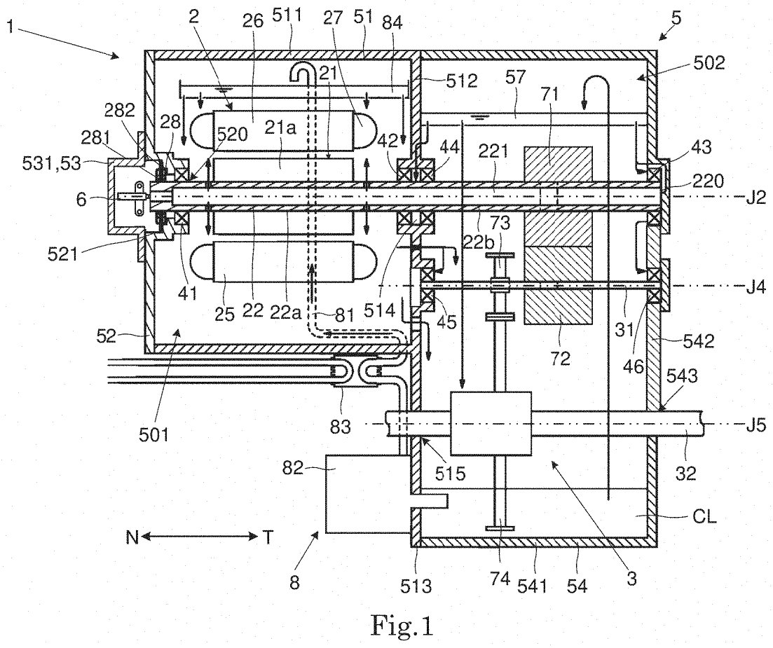

In the present specification, a direction parallel to a rotation axis J2 of a rotor 21 and a motor shaft 22 of a motor 2 is referred to as an “axial direction” of a motor unit 1. One axial side N and the other axial side T are defined as illustrated in FIG. 1. A radial direction orthogonal to the rotation axis J2 is simply referred to as a “radial direction”. A circumferential direction centered on the rotation axis J2 is simply referred to as a “circumferential direction”. A “parallel direction” described in the present specification includes not only a completely parallel direction, but also a substantially parallel direction. Then, “extending along” a predetermined direction or plane includes not only a case of extending strictly in a predetermined direction but also a case of extending in a direction inclined within a range of less than 45° with respect to the exact direction.

Hereinafter, an example of a motor unit according to an embodiment and modifications will be described with reference to FIGS. 1 to 10.

FIG. 1 is a conceptual diagram illustrating an example of the motor unit 1 according to the embodiment. Note that FIG. 1 is only a conceptual diagram. The arrangement and dimensions of each unit in FIG. 1 are not necessarily the same as those of the actual motor unit 1.

The motor unit 1 may be mounted on a vehicle as a power source. Examples of a vehicle include a hybrid vehicle (HV), a plug-in hybrid vehicle (PHV), and an electric vehicle (EV). Note that the motor unit 1 may be used as the power source of a vehicle other than an automobile.

Specifically, as illustrated in FIG. 1, the motor unit 1 includes the motor 2, a reduction gear 3, a housing 5, and an electrical discharging device 6. The housing 5 accommodates the motor 2, the reduction gear 3, and the electrical discharging device 6. The motor 2 includes the rotor 21 and a stator 25. The motor 2 includes the motor shaft 22 as a shaft. The motor shaft 22 is attached to the rotor 21 and rotates, and has a first helical gear 71 fixed thereto. The stator 25 covers the radially outer side of the rotor 21. The motor 2 is arranged on the one axial side N of the motor shaft 22. The reduction gear 3 is located on the other axial side T of the motor shaft 22.

The motor 2 is a DC brushless motor. Electric power for driving the motor 2 is supplied from an inverter (not illustrated). The rotor 21 includes the motor shaft 22 and rotates about the rotation axis J2. When the motor unit 1 is attached to the vehicle and the vehicle is on a horizontal plane, the rotation axis J2 extends in the horizontal direction. The stator 25 is located radially outward of the rotor 21. The motor 2 is an inner rotor type motor in which the rotor 21 is arranged inward of the stator 25 in a rotatable manner.

The rotor 21 rotates when an electric power is supplied to the stator 25 from an inverter. As illustrated in FIG. 1, the rotor 21 includes the motor shaft 22 and a rotor core 21a. The rotor 21 includes a rotor magnet (not illustrated). The motor shaft 22 is centered on the rotation axis J2 and extends in the vehicle width direction. The motor shaft 22 rotates about the rotation axis J2. Lubricating liquid CL (cooling liquid) described later flows inside the motor shaft 22. For example, the lubricating liquid CL is oil. For this reason, the motor shaft 22 includes a hollow part 221. The hollow part 221 is provided inside the motor shaft 22 and extends along the rotation axis J2. In other words, a cavity extending in the axial direction is provided inside the motor shaft 22. An inlet 220 is provided on the other axial side T of the motor shaft 22. The lubricating liquid CL flows into the hollow part 221 from the inlet 220. By providing the hollow part 221, a conductive wire can be arranged in the hollow part 221. The weight of the motor shaft 22 can also be reduced.

A first bearing 41, a second bearing 42, a third bearing 43, and a fourth bearing 44 are fixed to the housing 5. The first bearing 41, the second bearing 42, the third bearing 43, and the fourth bearing 44 support the motor shaft 22 in a rotatable manner.

The rotor core 21a is formed by laminating thin electromagnetic steel plates. The rotor core 21a is a columnar body extending along the axial direction. A plurality of rotor magnets are fixed to the rotor core 21a. The plurality of rotor magnets are aligned along the circumferential direction with the magnetic poles arranged alternately.

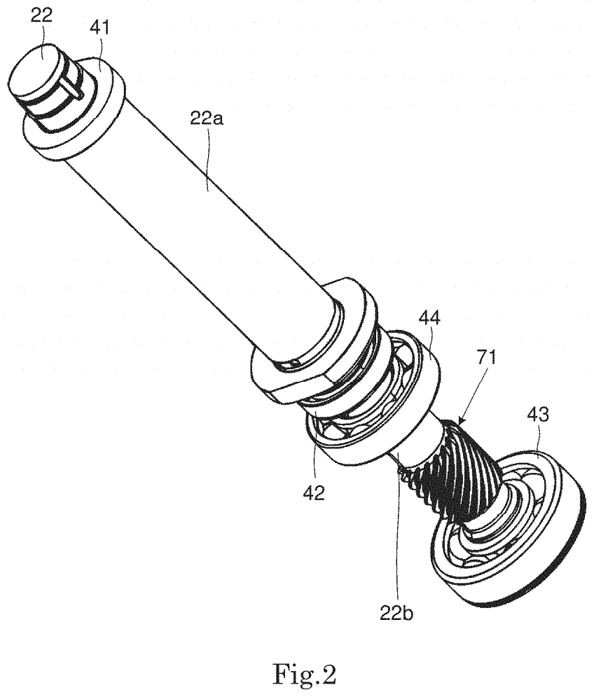

FIG. 2 is a diagram illustrating an example of the motor shaft 22 according to the embodiment. The motor shaft 22 may be dividable. For example, the motor shaft 22 can be divided into a part in a motor accommodation space 501 of the housing 5 and a part in a reduction gear accommodation space 502 of the housing 5. In the following description, the motor shaft 22 on the motor accommodation space 501 side and on the one axial side N is referred to as a first shaft 22a. The motor shaft 22 on the reduction gear accommodation space 502 side and on the other axial side T is referred to as a second shaft 22b.

FIG. 2 illustrates an example of the motor shaft 22 according to the embodiment. In FIG. 2, the upper part is the first shaft 22a and the lower part is the second shaft 22b. FIG. 2 illustrates a state in which the first bearing 41, the second bearing 42, the third bearing 43, and the fourth bearing 44 are attached.

The first shaft 22a and the second shaft 22b according to the embodiment may be connected by a spline fitting structure. In the case of the spline fitting structure, female splines are provided on an inner circumferential surface of one of the divided shafts, and male splines are provided on the other of the divided shafts.

Note that the first shaft 22a and the second shaft 22b may be connected by screw coupling using a male screw and a female screw. The first shaft 22a and the second shaft 22b may be connected by press-fitting or welding. When the fixing method such as press-fitting or welding is used, serrations combining recesses and protrusions extending in the axial direction may be used. Note that the motor shaft 22 may be formed as a single member.

The motor shaft 22 includes a first helical gear 71. That is, the first helical gear 71 is arranged on an outer circumferential surface of the motor shaft 22. As illustrated in FIG. 2, the first helical gear 71 may be provided on the second shaft 22b. The first helical gear 71 and the motor shaft 22 may be formed of a single member. The first helical gear 71 rotates about the rotation axis J2 together with the motor shaft 22.

The stator 25 includes a stator core (not illustrated). As illustrated in FIG. 1, the stator 25 includes a coil 27. The stator 25 includes an insulator (not illustrated). The stator 25 is held by the housing 5. The stator core includes a plurality of magnetic pole teeth (not illustrated) extending radially inward from an inner circumferential surface of an annular yoke. The coil 27 is formed by winding an electric wire around the magnetic pole teeth. The coil 27 is connected to an inverter unit (not illustrated) through a bus bar (not illustrated). Note that a bus bar (not illustrated) is arranged at an end part on the one axial side N inside the housing 5. The bus bar connects the inverter unit and the coil 27 and supplies electric power to the coil 27. Electric power is supplied to the coil 27 from the one axial side N.

A resolver 28 (see FIG. 1) is attached to an end part on the one axial side N of the motor shaft 22. The resolver 28 detects the position of the rotor 21, that is, the rotation angle. The resolver 28 includes a resolver rotor 281 fixed to the motor shaft 22 and a resolver stator 282 fixed to housing 5.

The resolver rotor 281 and the resolver stator 282 have an annular shape. An inner circumferential surface of the resolver stator 282 and an outer circumferential surface of the resolver rotor 281 face each other in the radial direction. The resolver stator 282 periodically detects the position of the resolver rotor 281 when the rotor 21 rotates. As a result, the resolver 28 acquires information on the position of the rotor 21.

The reduction gear 3 is accommodated in the housing 5 (reduction gear accommodation space 502). The reduction gear 3 includes a plurality of gears and a plurality of shafts. As described above, the reduction gear 3 is connected to the motor shaft 22 on the other axial side T. The reduction gear 3 includes a counter shaft 31 and an output shaft 32.

The counter shaft 31 extends along an intermediate axis J4. The intermediate axis J4 is parallel to the rotation axis J2. Both axial ends of the counter shaft 31 pass through the through holes of a fifth bearing 45 and a sixth bearing 46, respectively. The counter shaft 31 is rotatably supported by the fifth bearing 45 and the sixth bearing 46. These bearings are provided in the housing 5. That is, the counter shaft 31 is rotatable about the intermediate axis J4. The counter shaft 31 includes a second helical gear 72 which is a middle drive gear and a third gear 73 which is a final drive gear.

The second helical gear 72 and the third gear 73 are arranged on the counter shaft 31. The second helical gear 72 meshes with the first helical gear 71. The third gear 73 meshes with a ring gear 74 of the output shaft 32. The torque of the motor shaft 22 is transmitted to the second helical gear 72 from the first helical gear 71. Then, the torque transmitted to the second helical gear 72 is transmitted to the third gear 73 through the counter shaft 31. The torque transmitted to the third gear 73 is transmitted to the ring gear 74 of the output shaft 32. In this manner, the counter shaft 31 transmits the output torque of the motor 2 to the output shaft 32. The gear ratio of each gear and the number of gears can be variously changed according to the required reduction ratio.

The output shaft 32 extends along an output axis J5. The output axis J5 is parallel to the rotation axis J2 and the intermediate axis J4. The output shaft 32 is rotatable about the output axis J5. The output shaft 32 protrudes to the outside of the housing 5. A drive shaft (not illustrated) connected to a drive wheel of the vehicle is connected to the output shaft 32. The torque of the output shaft 32 is transmitted to the drive wheel. The output shaft 32 may include a mechanism that absorbs the speed difference between the left and right drive wheels and transmits the same torque to the left and right of the output shaft 32 when the vehicle turns.

Thus, the counter shaft 31 is connected to the motor shaft 22. The counter shaft 31 transmits the output torque of the motor 2 to the output shaft 32. The counter shaft 31 decreases the rotational speed of the motor 2 according to the reduction ratio. The counter shaft 31 increases the output torque of the motor 2 according to the reduction ratio. Note that the reduction gear 3 may have a parking mechanism (not illustrated) that locks the vehicle when the operation of the motor unit 1 is stopped.

As illustrated in FIG. 1, the housing 5 includes a first housing 51, a bearing holder 52, a cover member 53, and a second housing 54. The first housing 51 accommodates the stator 25 and the rotor 21. The second housing 54 is located on the other axial side T of the first housing 51. The second housing 54 accommodates the reduction gear 3. The housing 5 includes the cover member 53. In the embodiment, a first cover member 531 is provided as the cover member 53. The first cover member 531 covers the electrical discharging device 6 from the outside of the housing 5 in the axial direction. The cover member 53 accommodates the electrical discharging device 6 in the housing 5. As a result, the electrical discharging device 6 can be accommodated in the housing 5.

The first housing 51, the bearing holder 52, the first cover member 531, and the second housing 54 are formed of a conductive metal. For example, the material of the housing 5 may be iron, aluminum, or an alloy thereof. However, the material is not limited thereto. Note that the materials of the first housing 51, the bearing holder 52, the first cover member 531, and the second housing 54 may be the same or may be different.

The first housing 51 includes a first tube part 511, a partition wall 512, and a protrusion 513. The first tube part 511 is a tubular body extending in the axial direction. The first tube part 511 has an opening on the one axial side N. The partition wall 512 expands radially inward from an end part on the other axial side T of the first tube part 511. The partition wall 512 is provided with a through hole 514 penetrating along the rotation axis J2. The through hole 514 has a circular cross section, and its center line overlaps with the rotation axis J2. Then, the motor shaft 22 penetrates the through hole 514. The motor shaft 22 is rotatably supported by the partition wall 512 with the second bearing 42 and the fourth bearing 44 interposed therebetween. The second bearing 42 is arranged on the one axial side N of the through hole 514 of the partition wall 512. The fourth bearing 44 is arranged on the other axial side T of the through hole 514 of the partition wall 512. As a result, the motor shaft 22 is rotatably supported at its intermediate part in the axial direction. This curbs shaking, deflection, and the like of the rotating motor shaft 22.

The protrusion 513 has a flat plate shape. The protrusion 513 extends vertically downward from the other axial side T of an outer circumferential surface of the first tube part 511. In the motor unit 1, the first tube part 511, the partition wall 512, and the protrusion 513 are formed of a single member. The partition wall 512 and the protrusion 513 close an end part on the one axial side N of the second housing 54.

A first drive shaft passage hole 515 is provided in the protrusion 513. The first drive shaft passage hole 515 is a hole axially penetrating the protrusion 513. The output shaft 32 penetrates the first drive shaft passage hole 515 in a rotatable state. An oil seal (not illustrated) is provided between the output shaft 32 and the first drive shaft passage hole 515 to curb leakage of the lubricating liquid CL. An axle (not illustrated) that rotates the wheel is connected to the tip end of the output shaft 32.

The bearing holder 52 expands in the radial direction. The bearing holder 52 is fixed to the one axial side N of the first tube part 511 with screws. However, the fixing method is not limited thereto. The bearing holder 52 may be firmly fixed using other methods such as screwing and press-fitting.

As a result, the bearing holder 52 is electrically connected to the first housing 51. The term “electrically connected” includes a case where members are physically in contact with each other and can be electrically conducted, and also includes a case where members are close to each other to an extent of being substantially at the same potential. That is, electrically connected members have the same or substantially the same potential. Hereinafter, the term “electrically connected” refers to a similar configuration. In the motor unit 1, the first housing 51 and the bearing holder 52 have the same potential. Note that the housing 5 is grounded. In other words, the housing 5 is electrically connected to the ground. Electric charge of the housing 5 flows toward the earth.

The first tube part 511 and the bearing holder 52 are in close contact with each other. Here, close contact means to have such a sealing property that the lubricating liquid CL inside the housing 5 does not leak to the outside and that foreign matters such as external water, dust, and the like do not enter. Hereinafter, the term “close contact” refers to a similar configuration.

The bearing holder 52 includes a recess 521. The recess 521 is recessed to the other axial side T from a surface on the one axial side N of the bearing holder 52. A through hole 520 axially penetrates a bottom surface of the recess 521. The center of the through hole 520 coincides with the rotation axis J2, and the motor shaft 22 penetrates the through hole 520. The end part on the one axial side N of the motor shaft 22 is arranged inside the recess 521.

The first bearing 41 is arranged on the other axial side T of the bearing holder 52. The motor shaft 22 penetrating the through hole 520 is rotatably supported by the bearing holder 52 with the first bearing 41 interposed therebetween.

The resolver stator 282 of the resolver 28 is fixed to the inside of the recess 521. That is, the resolver stator 282 is fixed to the bearing holder 52. The center line of the resolver stator 282 arranged in the bearing holder 52 coincides with the rotation axis J2. The resolver stator 282 may be fixed to the bearing holder 52 by a screw (not illustrated). The resolver stator 282 may be fixed to the bearing holder 52 by press-fitting or adhesion. Other fixing methods may be employed.

The motor shaft 22 on the other axial side T of the rotor core 21a penetrates the through hole 514. A part of the motor shaft 22 on the one axial side N of the rotor core 21a penetrates the through hole 520. Then, both sides of the motor shaft 22 across the rotor core 21a in the axial direction are rotatably supported by the housing 5 with the first bearing 41 and the second bearing 42 interposed therebetween. At this time, the motor shaft 22 is rotatable about the rotation axis J2.

The first cover member 531 is attached to the one axial side N of the bearing holder 52. The first cover member 531 covers the recess 521 of the bearing holder 52 from the one axial side N. The first cover member 531 is in close contact with the bearing holder 52. The bearing holder 52 and the first cover member 531 are electrically connected. For this reason, the first cover member 531 and the first housing 51 have the same potential. Hence, electric charge of the first cover member 531 is removed.

The second housing 54 has a recessed shape opened to the one axial side N. The second housing 54 includes a second tube part 541 and a closing part 542. An end part on the one axial side N of the second tube part 541 is attached to the partition wall 512 of the first housing 51. The second tube part 541 overlaps an outer edge part of the partition wall 512 in the axial direction. The second tube part 541 is in close contact and electrical contact with the partition wall 512. The second tube part 541 may be fixed to the partition wall 512 by screwing, or may be fixed by welding or press-fitting. Other fixing methods may be employed. The opening of the second tube part 541 is covered with the partition wall 512.

The second tube part 541 and the closing part 542 are formed of a single member. The closing part 542 has a plate shape expanding radially inward from an end part on the other axial side T of the second tube part 541. A space surrounded by the second tube part 541, the closing part 542, and the partition wall 512 is the reduction gear accommodation space 502. The end part on the other axial side T of the motor shaft 22 is rotatably supported by the closing part 542 with the third bearing 43 interposed therebetween.

A second drive shaft passage hole 543 is formed in the closing part 542. The second drive shaft passage hole 543 is a hole axially penetrating the closing part 542. The output shaft 32 penetrates the second drive shaft passage hole 543 in a rotatable state. An oil seal (not illustrated) is provided between the output shaft 32 and the second drive shaft passage hole 543 to curb leakage of the lubricating liquid CL. The output shaft 32 rotates about the output axis J5.

The lubricating liquid CL fills the inside of the housing 5. The lubricating liquid CL lubricates each gear and bearing of the reduction gear 3. The lubricating liquid CL is also used for cooling the motor 2. That is, the lubricating liquid CL for lubricating the motor unit 1 is also a coolant of the motor 2.

As illustrated in FIG. 1, the lubricating liquid CL accumulates in a lower region of the reduction gear accommodation space 502. A part (ring gear 74) of the output shaft 32 is immersed in the lubricating liquid CL stored in the reduction gear accommodation space 502. The stored lubricating liquid CL is scraped up by the operation of the output shaft 32 and is scattered into the reduction gear accommodation space 502. The scraped up lubricating liquid CL is supplied to each gear in the reduction gear accommodation space 502. The scraped up lubricating liquid CL is also supplied to each bearing. The lubricating liquid CL is used to lubricate each gear and bearing.

As illustrated in FIG. 1, an oil reserve tray 57 is arranged in an upper region of the reduction gear accommodation space 502. The oil reserve tray 57 opens upward. A part of the scraped up lubricating liquid CL flows into the oil reserve tray 57. The lubricating liquid CL accumulated in the oil reserve tray 57 flows into the hollow part 221 of the motor shaft 22 through an oil supply path (not illustrated) and the inlet 220. The lubricating liquid CL in the hollow part 221 flows toward the one axial side N. The lubricating liquid CL having flowed through the hollow part 221 is sprayed onto the stator 25. As a result, the lubricating liquid CL cools the stator 25 as well.

When the motor shaft 22 rotates, the airflow escapes to the one axial side N, whereby a negative pressure is generated. This negative pressure allows the lubricating liquid CL to be drawn into the motor shaft 22 from the inlet 220. As a result, the lubricating liquid CL can be supplied to the entire motor 2. The motor 2 can be cooled reliably.

The motor unit 1 includes a liquid circulation part 8 that circulates the lubricating liquid CL. The liquid circulation part 8 includes a pipe part 81, a pump 82, an oil cooler 83, and a motor oil reservoir 84. The pipe part 81 is a pipe formed in the housing 5. The pipe part 81 joins the pump 82 and the motor oil reservoir 84 arranged inside the first tube part 511. The pipe part 81 supplies the lubricating liquid CL to the motor oil reservoir 84. The pump 82 sucks the lubricating liquid CL stored in the lower region of the reduction gear accommodation space 502. The pump 82 may be an electric pump 82. The pump 82 may be driven using a part of the output of the output shaft 32 of the motor unit 1. A pump 82 other than those described above may be used.

The oil cooler 83 is arranged between the pump 82 and the motor oil reservoir 84. That is, the lubricating liquid CL sucked by the pump 82 passes through the oil cooler 83 through the pipe part 81, and is sent to the motor oil reservoir 84. For example, a refrigerant supplied from the outside is supplied to the oil cooler 83. The refrigerant is, for example, water. Then, heat is exchanged between the refrigerant and the lubricating liquid CL to lower the temperature of the lubricating liquid CL. Note that the oil cooler 83 is not limited to the liquid-cooled type. The oil cooler 83 may be an air-cooled type that cools with traveling air of the vehicle. By using the oil cooler 83, the cooling efficiency of the motor 2 can be enhanced.

The motor oil reservoir 84 is arranged in an upper region of the motor accommodation space 501. The motor oil reservoir 84 is a tray opened upward. A dropping hole is formed in a bottom part of the motor oil reservoir 84. The lubricating liquid CL dropped from the dropping hole cools the motor 2. The dropping hole is formed, for example, above the coil 27 of the stator 25, and the coil 27 is cooled by the lubricating liquid CL.

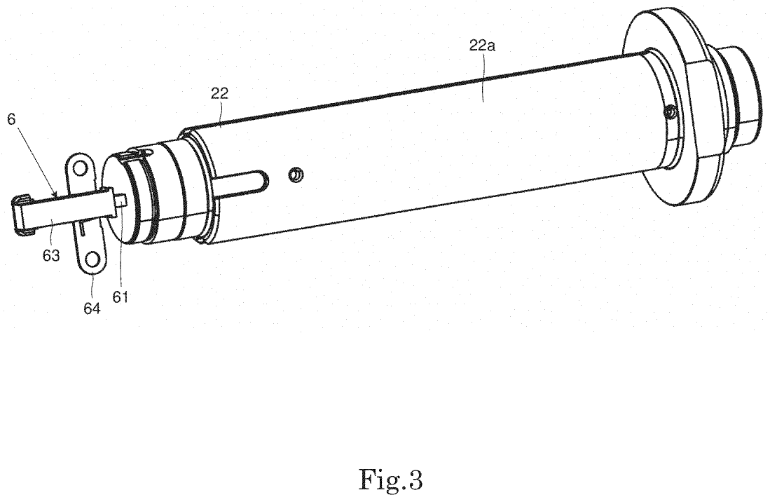

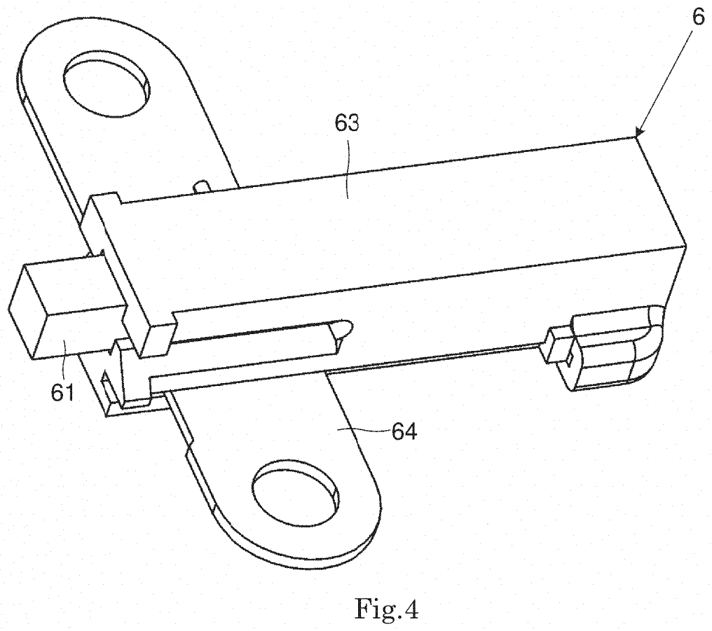

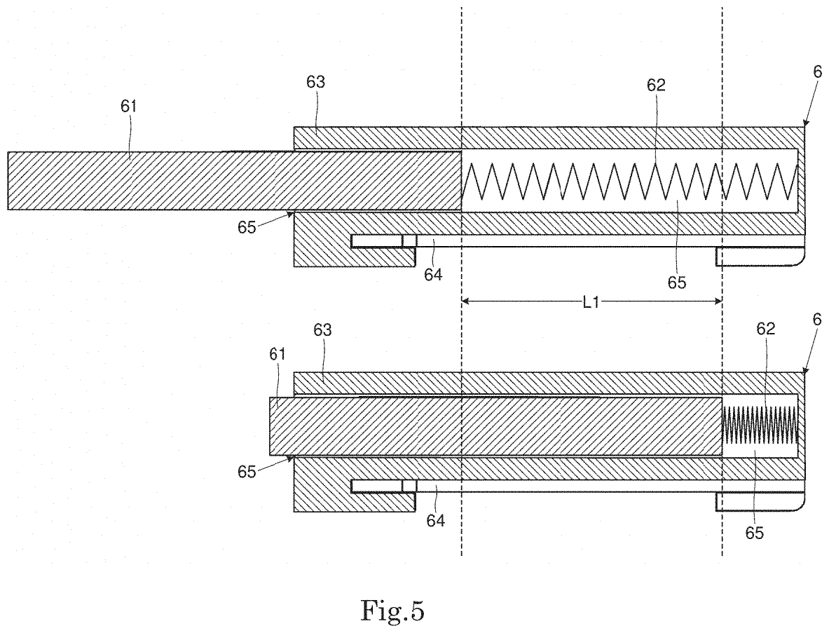

An example of the electrical discharging device 6 according to the embodiment will be described with reference to FIGS. 1 and 3 to 5. FIG. 3 is a diagram illustrating an example of the electrical discharging device 6 and the shaft according to the embodiment. FIGS. 4 and 5 are diagrams illustrating an example of the electrical discharging device 6 according to the embodiment.

First, at least one electrical discharging device 6 is provided in the motor unit 1. In the description of the embodiment, an example in which the electrical discharging device 6 is provided on the one axial side N of the motor shaft 22 will be described. That is, in the motor unit 1 according to the embodiment, in the description of the present embodiment, the shaft in contact with a contact member 61 of the electrical discharging device 6 is the motor shaft 22 that is attached to the rotor 21 and rotates. Electric charge accumulated in the motor shaft 22 can be removed.

The contact member 61 of the electrical discharging device 6 is in contact with the end face on one axial side of the motor shaft 22 (see FIG. 1). Specifically, electric charge of the shaft can be removed at the end part on the one axial side N of the motor shaft 2.

FIG. 3 illustrates an example of contact between the electrical discharging device 6 and the end face of the motor shaft 22. The end face of the motor shaft 22 is a surface of an end part of the motor shaft 22, and is a surface expanding in the radial direction. In the example of FIG. 3, the end face is perpendicular to the axial direction and the circumferential direction, and is parallel to the radial direction.

As illustrated in FIGS. 3 to 5, the electrical discharging device 6 includes the contact member 61. The contact member 61 is in contact with the end face. For example, the center of the end face coincides with the center of the contact member 61. The contact member 61 has conductivity. The electrical discharging device 6 includes a biasing member 62 and a case 63. As illustrated in FIGS. 4 and 5, the case 63 accommodates the contact member 61 and the biasing member 62. As illustrated in FIG. 5, the biasing member 62 biases the contact member 61. The biasing member 62 biases the contact member 61 toward the end face of the shaft (motor shaft 22) in a direction parallel to the axial direction of the shaft. The contact member 61 has conductivity and comes into contact with the end face by the biasing of the biasing member 62.

The case 63 is in contact with the first cover member 531 of the motor unit 1 or the bearing holder 52. Then, the case 63 may include a fixing plate 64. In FIGS. 4 and 5, an elliptical plate in plan view is illustrated as an example of the fixing plate 64. As illustrated in FIGS. 4 and 5, the fixing plate 64 may include a through hole. FIGS. 4 and 5 illustrate an example in which the fixing plate 64 includes two through holes. Note that the fixing plate 64 may include a through hole, and may include one, or three or more through holes.

The fixing plate 64 is a member for fixing the electrical discharging device 6. For example, protrusions provided on the housing 5 and the first cover member 531 may pass through the through holes of the fixing plate 64. The position of the electrical discharging device 6 may be fixed in this manner. Further, the electrical discharging device 6 may be connected and fixed to the first cover member 531. As a result, the electrical discharging device 6 can be arranged at a position facing the end face. The fixing plate 64 can be used for electrical connection between the contact member 61 and the housing 5 (cover member 53 or bearing holder 52). The fixing plate 64 and the housing 5 may be connected by a conductive wire. The material of the fixing plate 64 is, for example, a conductive metal. For example, the conductive metal may be iron, aluminum, copper, or an alloy thereof. However, the material is not limited thereto.

The material of the contact member 61 and the case 63 (including fixing plate 64) is, for example, a conductive metal. For example, the conductive metal may be iron, aluminum, copper, or an alloy thereof. However, the material is not limited thereto. Note that the material of the contact member 61 may be the same as the material of the motor shaft 22. As a result, the contact member 61 is electrically connected to the housing 5. Since the contact member 61 and the housing 5 are electrically connected, the electric charge of the motor shaft 22 flows to the housing 5 through the contact member 61. That is, the motor shaft 22 is neutralized and grounded.

Here, the motor shaft 22 is a shaft in which the first shaft 22a and the second shaft 22b are connected in the axial direction. The motor shaft 22 (first shaft 22a) is attached to the rotor 21 and rotates. Then, the contact member 61 may be in contact with the end face on the first shaft 22a side. As a result, electric charge accumulated in the connected (spline-fitted) motor shaft 22 can be removed. For this reason, even in a case of using a shaft in which a plurality of members are connected, the electrical discharging device 6 can cope with the pushing force of the motor shaft 22 even if the motor shaft 22 including the first helical gear 71 moves in the axial direction.

Next, an example of the contact member 61 will be described with reference to FIG. 5. FIG. 5 is a cross-sectional view of the electrical discharging device 6 taken along a plane including the rotation axis J2 in a state where the contact member 61 is brought into contact with the end face.

As illustrated in FIG. 5, the case 63 has a recessed cross section parallel to the axial direction. The case includes a hole 65 extending in the axial direction. The biasing member 62 is arranged on the back side of the hole 65. The contact member 61 is arranged on the opening side of the hole 65. Moreover, the contact member 61 can be kept in contact with the end face of the shaft by the biasing member 62. When the electrical discharging device 6 is attached to the motor unit 1, the longitudinal direction of the hole 65 is parallel to the axial direction. In other words, the case 63 has a tubular shape. The opening of the hole 65 is provided on a surface facing the end face of the motor shaft 22. The biasing member 62 is provided on the back side of the hole 65. The contact member 61 is arranged closer to the opening side of the hole 65 than the biasing member 62.

For example, the contact member 61 is a metal rod member. One end of the contact member 61 in the longitudinal direction is inserted into the hole 65. The other end of the contact member 61 in the longitudinal direction is in contact with the end face of the motor shaft 22. The contact member 61 illustrated in FIGS. 3 and 4 has a quadrangular prism shape. However, the contact member 61 may have a columnar shape or a prism shape other than a square.

The biasing member 62 biases the contact member 61 in the axial direction toward the end face of the motor shaft 22. Even if the length of the contact member 61 changes due to wear, the contact member 61 is kept in contact with the end face due to biasing. For example, the biasing member 62 is a coil spring. Note that the biasing member 62 may be a spring other than the coil spring. The biasing member 62 is not limited to a spring.

The stroke of the contact member 61 will be described with reference to FIG. 5. The stroke in the present description means a length (distance) of reciprocation in the axial direction of the contact member 61 in the hole 65. The upper diagram of FIG. 5 illustrates an example of a state in which the contact member 61 protrudes to the maximum (hereinafter referred to as state A). The lower diagram of FIG. 5 illustrates an example of a state in which the contact member 61 is pushed into the hole 65 to the maximum (hereinafter referred to as state B).

The biasing member 62 is provided on the back side (hole bottom) of the hole 65 in the axial direction. The contact member 61 may be pushed into the hole 65 until the biasing member 62 is fully compressed. In other words, there is an upper limit on the amount (distance) by which the contact member 61 can be pushed into the hole 65. A part of the contact member 61 needs to be inserted into the hole 65. There is also an upper limit on the amount (distance) by which the contact member 61 is pushed out toward the end face.

Specifically, a maximum stroke amount L1 of the contact member 61 in the axial direction is determined. The maximum stroke amount L1 of the contact member 61 in the axial direction is an axial length from the position of an end part on the back side of the hole 65 of the contact member 61 in state A to the position of the end part on the back side of the hole 65 of the contact member 61 in state B. A bidirectional arrow in FIG. 5 indicates an example of the maximum stroke amount L1 of the contact member 61 in the axial direction.

Here, the motor shaft 22 includes the first helical gear 71. A helical gear is superior to a spur gear in terms of smoothness and strength of meshing, and has an advantage of being silent. However, when torque is applied to the helical gear, an axial force (thrust load) is generated. Note that bearings that sufficiently withstand axial force (thrust) are used for the first bearing 41, the second bearing 42, the third bearing 43, and the fourth bearing 44. A connection part between the first shaft 22a and the second shaft 22b also withstands axial force (thrust).

When the motor shaft 22 is rotated, the motor shaft 22 moves to the one axial side N or the other axial side T by the axial force of the first helical gear 71. The moving direction depends on the twisting direction of the first helical gear 71 and the rotation direction of the motor 2. It is preferable that even when the motor shaft 22 moves, the contact member 61 is kept in contact with the end face of the motor shaft 22. It is preferable to continue to contact the end face of the motor shaft 22. It is also preferable that even when the motor shaft 22 moves to the maximum extent, the contact member 61 is not pushed into the hole 65 beyond the limit.

Hence, the maximum stroke amount L1 of the contact member 61 in the axial direction is larger than the movement width of the shaft (motor shaft 22) in the axial direction during rotation. On the one axial side N, the movement width of the motor shaft 22 in the axial direction during rotation can be measured in advance. The maximum stroke amount L1 of the contact member 61 of the electrical discharging device 6 in the axial direction is larger than the measured movement width of the motor shaft 22 in the axial direction.

As a result, the electric charge accumulated in the motor shaft 22 flows to the housing 5 through the contact member 61. For this reason, the electric charge accumulated in the motor shaft 22 can be removed by the electrical discharging device 6. Then, in the case of using a helical gear, when the motor shaft 22 rotates, the motor shaft 22 moves in the axial direction. Since the contact member 61 is biased in the axial direction, the contact member 61 is kept in contact with the end face of the motor shaft 22 even if the motor shaft 22 moves in the axial direction. Hence, the electric charge of the motor shaft 22 can be continuously removed. Here, the motor shaft 22 may move in the axial direction and push the contact member 61 of the electrical discharging device 6 with strong force. However, the stroke amount of the contact member 61 in the axial direction is larger than the movement width of the motor shaft 22 in the axial direction. Accordingly, even if the motor shaft 22 is pushed by using the helical gear, the electrical discharging device 6 can cope with the pushing force.

Specifically, the electrical discharging device 6 is arranged at a position where the contact member 61 can still be pushed into the back side (one axial side N) of the hole 65 in the axial direction in a state where the motor shaft 22 is moved to the one axial side N to the maximum extent. The electrical discharging device 6 is arranged at a position where the contact member 61 is in contact with the end face of the motor shaft 22 even in a state where the motor shaft 22 is located closest to the other axial side T. That is, the electrical discharging device 6 is arranged at a position where the biasing member 62 does not bias the contact member 61 to the maximum extent in a state where the motor shaft 22 is located closest to the other axial side T.

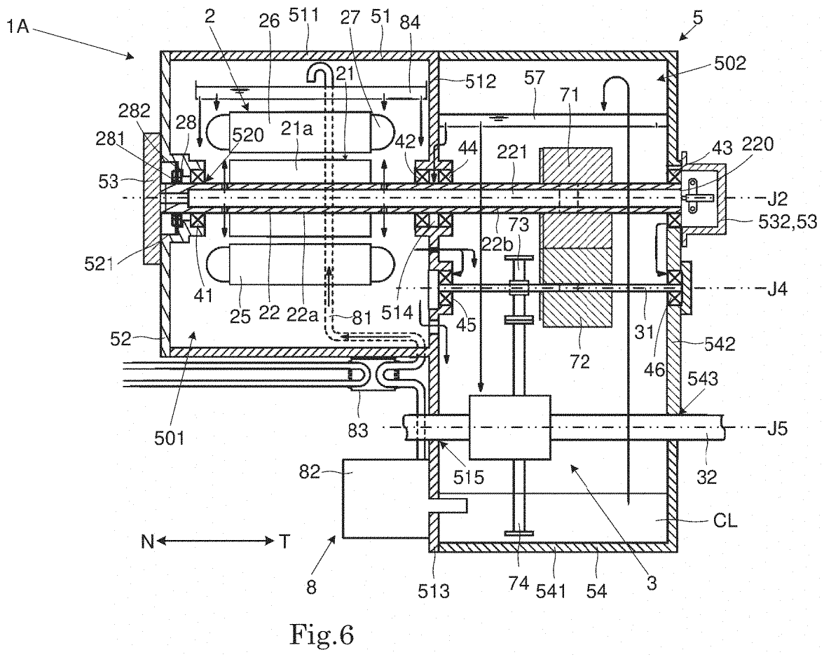

Next, a motor unit 1A according to a first modification will be described with reference to FIG. 6. The motor unit 1A according to the first modification is different from the motor unit 1 according to the embodiment in the installation position of an electrical discharging device 6. However, points other than the installation position are similar to those of the motor unit 1 according to the embodiment. For example, the configuration of the electrical discharging device 6 and the point that the electrical discharging device 6 and a contact member 61 are electrically connected to a housing 5 are common. Detailed description of the same parts is omitted unless otherwise specified. The description of the embodiment is incorporated in the description omitted.

FIG. 6 is a diagram illustrating an example of the motor unit 1A according to the first modification. As illustrated in the first modification, the shaft in contact with the electrical discharging device 6 may be a motor shaft 22 that is attached to a rotor 21 and rotates. Then, the contact member 61 may be in contact with an end face on the other axial side T of the motor shaft 22. That is, the electrical discharging device 6 may be provided at a position where the contact member 61 is in contact with an end face on one axial side N of the motor shaft 22. FIG. 6 illustrates an example in which the contact member 61 is in contact with the end face on the other axial side T of the motor shaft 22. In the case of FIG. 6, a second shaft 22b and the contact member 61 are in contact with each other.

Note that as a cover member 53, a second cover member 532 that covers the electrical discharging device 6 provided on the other axial side T may be provided. In this case, the cover member 53 (second cover member 532) covers the electrical discharging device 6 from the outside of a housing 5 in the axial direction. The second cover member 532 accommodates the electrical discharging device 6 in the housing 5. The electrical discharging device 6 may be connected and fixed to the second cover member 532. The second cover member 532 is fixed to a second housing 54. The electrical discharging device 6 is electrically connected to the housing 5.

On the other axial side T, the movement width of the motor shaft 22 in the axial direction during rotation can be measured in advance. In the first modification, too, a maximum stroke amount L1 of the contact member 61 of the electrical discharging device 6 in the axial direction is larger than the measured movement width of the motor shaft 22 in the axial direction.

Electric charge accumulated in the motor shaft 22 can be removed. Specifically, electric charge of the shaft can be removed at an end part on the other axial side T of the motor shaft 22. Further, even when the contact member 61 is brought into contact with the end face close to a first helical gear 71 and susceptible to the movement of the motor shaft 22, the electrical discharging device 6 can cope with the pushing force of the motor shaft 22 due to the movement in the axial direction.

Specifically, the electrical discharging device 6 is arranged at a position where the contact member 61 can still be pushed into the back side (other axial side T) of the hole 65 in the axial direction in a state where the motor shaft 22 is moved to the other axial side T to the maximum extent. The electrical discharging device 6 is arranged at a position where the contact member 61 is in contact with the end face of the motor shaft 22 even in a state where the motor shaft 22 is located closest to the one axial side N. That is, the electrical discharging device 6 is arranged at a position where the biasing member 62 does not bias the contact member 61 to the maximum extent in a state where the motor shaft 22 is located closest to the one axial side N.

Here, the contact member 61 is in contact with the end face on the second shaft 22b side. Electric charge accumulated in the connected (spline-fitted) motor shaft 22 can be removed. Even in a case of using a shaft in which a plurality of members are connected, the electrical discharging device 6 can cope with a pressing force based on the movement of the motor shaft 22 in the axial direction.

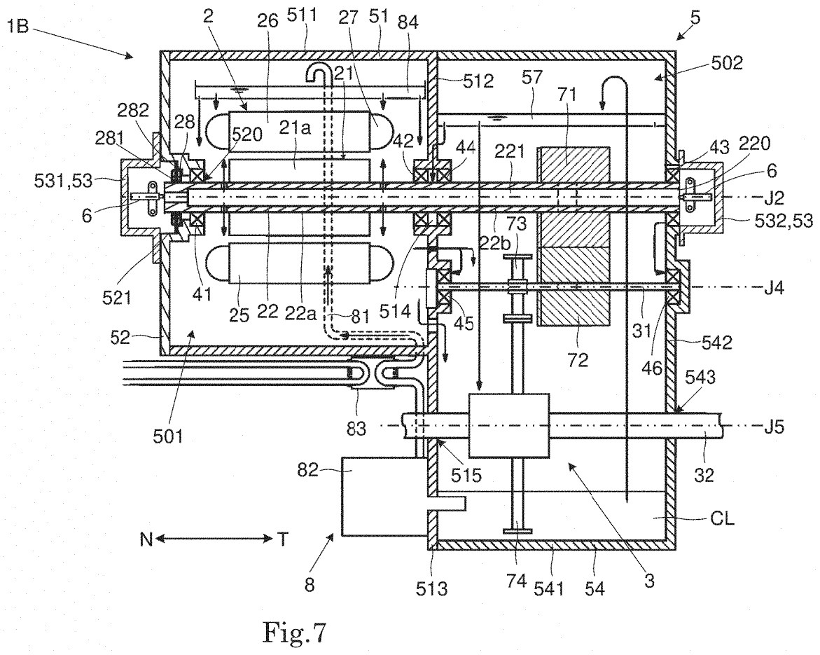

Next, a motor unit 1B according to a second modification will be described with reference to FIG. 7. The motor unit 1B according to the second modification is different from the motor unit 1 according to the embodiment in the installation position of an electrical discharging device 6. However, points other than the installation position are similar to those of the motor unit 1 according to the embodiment. For example, the configuration of the electrical discharging device 6 and the point that the electrical discharging device 6 and a contact member 61 are electrically connected to a housing 5 are common. Detailed description of the same parts is omitted unless otherwise specified. The description of the embodiment is incorporated in the description omitted.

FIG. 7 is a diagram illustrating an example of the motor unit 1B according to the second modification. As illustrated in the second modification, the shaft in contact with the contact member 61 may be a motor shaft 22 that is attached to a rotor 21 and rotates. A plurality of electrical discharging devices 6 are provided. One electrical discharging device 6 may be provided at a position where the contact member 61 is in contact with an end face on one axial side N of the motor shaft 22. Further, another electrical discharging device 6 may be provided at a position where the contact member 61 is in contact with an end face on the other axial side T of the motor shaft 22. In other words, a first electrical discharging device 6 may be provided on the one axial side N of the end face on the one axial side N of the motor shaft 22. Additionally, a second electrical discharging device 6 may be provided on the other axial side T of the end face on the other axial side T of the motor shaft 22. Note that similarly to the embodiment, a first cover member 531 that covers the electrical discharging device 6 provided on the other axial side N may be provided. The electrical discharging device 6 on the one axial side N is electrically connected to the housing 5.

Similarly to the first modification, as a cover member 53, a second cover member 532 that covers the electrical discharging device 6 provided on the other axial side T may be provided. In this case, the cover member 53 (second cover member 532) covers the electrical discharging device 6 from the outside of a housing 5 in the axial direction. The cover member 53 accommodates the electrical discharging device 6 in the housing 5. The electrical discharging device 6 may be connected and fixed to the second cover member 532. The second cover member 532 is fixed to a second housing 54. The electrical discharging device 6 is electrically connected to the housing 5.

The electrical discharging device 6 can be provided at both axial ends of the motor shaft 22. Electric charge accumulated in the motor shaft 22 can be efficiently removed. Discharge at the bearing in contact with the motor shaft 22 can be reduced as much as possible.

On the one axial side N, the movement width of the motor shaft 22 in the axial direction during rotation can be measured in advance. In the electrical discharging device 6 on the one axial side N, a maximum stroke amount L1 of the contact member 61 in the axial direction is larger than the measured movement width of the motor shaft 22 on the one axial side N. Specifically, the electrical discharging device 6 on the one axial side N is arranged at a position where the contact member 61 can still be pushed into the back side (one axial side N) of a hole 65 in the axial direction in a state where the motor shaft 22 is moved to the one axial side N to the maximum extent. The electrical discharging device 6 on the one axial side N is arranged at a position where the contact member 61 is in contact with the end face of the motor shaft 22 even in a state where the motor shaft 22 is located closest to the other axial side T. That is, the electrical discharging device 6 on the one axial side N is arranged at a position where a biasing member 62 does not bias the contact member 61 to the maximum extent in a state where the motor shaft 22 is located closest to the other axial side T.

On the other axial side T, the movement width of the motor shaft 22 in the axial direction during rotation can be measured in advance. In the electrical discharging device 6 on the other axial side T, the maximum stroke amount L1 of the contact member 61 in the axial direction is larger than the measured movement width of the motor shaft 22 on the other axial side T. Specifically, the electrical discharging device 6 on the other axial side T is arranged at a position where the contact member 61 can still be pushed into the back side (other axial side T) of the hole 65 in the axial direction in a state where the motor shaft 22 is moved to the other axial side T to the maximum extent. The electrical discharging device 6 on the other axial side T is arranged at a position where the contact member 61 is in contact with the end face of the motor shaft 22 even in a state where the motor shaft 22 is located closest to the one axial side N. That is, the electrical discharging device 6 on the other axial side T is arranged at a position where the biasing member 62 does not bias the contact member 61 to the maximum extent in a state where the motor shaft 22 is located closest to the one axial side N.

Next, a motor unit 1 according to a third modification will be described. The third modification differs from the embodiment, the first modification, and the second modification in the reference of the installation position of an electrical discharging device 6. When a helical gear is used, the movement width of an end part of the shaft in the axial direction during rotation may be different between one side and the other side in the axial direction. For example, there may be a difference in the movement width in the axial direction depending on the number of bearings from the helical gear to the end face. As illustrated in the third modification, the shaft in contact with the electrical discharging device 6 (contact member 61) may be a motor shaft 22 that is attached to a rotor 21 and rotates. The electrical discharging device 6 may be provided at a position where the contact member 61 is in contact with one of an end face on one axial side N of the motor shaft 22 and an end face on the other axial side T of the motor shaft 22, the end face having a smaller movement width in the axial direction during rotation.

The electrical discharging device 6 can be provided at a position where the contact member 61 is in contact with the end face having a smaller movement width in the axial direction. The maximum stroke amount of the contact member 61 in the axial direction can be reduced as compared with a case where the electrical discharging device 6 is provided at a position where the contact member 61 is in contact with the end face having a larger movement width in the axial direction. The electrical discharging device 6 can be downsized.

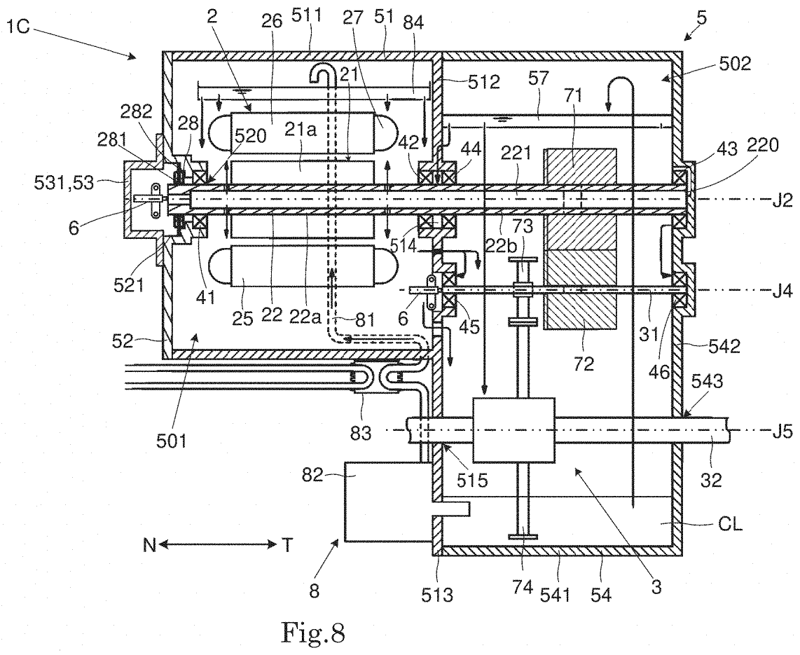

Next, a motor unit 1C according to a fourth modification will be described with reference to FIG. 8. The motor unit 1C according to the fourth modification is different from the motor unit 1 according to the embodiment in the installation position of an electrical discharging device 6. However, points other than the installation position are similar to those of the motor unit 1 according to the embodiment. For example, the configuration of the electrical discharging device 6 and the point that the electrical discharging device 6 and a contact member 61 are electrically connected to a housing 5 are common. Detailed description of the same parts is omitted unless otherwise specified. The description of the embodiment is incorporated in the description omitted.

FIG. 8 is a diagram illustrating an example of the motor unit 1C according to the fourth modification. As illustrated in the fourth modification, a reduction gear 3 includes a counter shaft 31 including a second helical gear 72 that meshes with a first helical gear 71. The electrical discharging device 6 is provided at a position where an end face on one axial side N of the counter shaft 31 is in contact with the contact member 61. In other words, the electrical discharging device 6 may be provided on the one axial side N of an end face on the one axial side N of the counter shaft 31. Note that bearings that sufficiently withstand axial force (thrust) are used for a fifth bearing 45 and a sixth bearing 46 that support the counter shaft 31. In this case, the electrical discharging device 6 is fixed to a second housing 54. The electrical discharging device 6 is electrically connected to the housing 5.

It is possible to remove electric charge accumulated in the counter shaft 31 that rotates by being driven by the motor shaft 22. Specifically, electric charge of the counter shaft 31 can be removed at an end part on the one axial side N of the second helical gear 72. Further, when the counter shaft 31 including the second helical gear 72 moves in the axial direction, the counter shaft 31 may push the contact member 61 of the electrical discharging device 6 with strong force. However, the stroke amount of the contact member 61 in the axial direction is larger than the movement width of the motor shaft 22 in the axial direction. Accordingly, even when the counter shaft 31 pushes, the electrical discharging device 6 can cope with the pushing force.

On the one axial side N, the movement width of the counter shaft 31 in the axial direction during rotation can be measured in advance. In the electrical discharging device 6 on the one axial side N, a maximum stroke amount L1 of the contact member 61 in the axial direction is larger than the measured movement width of the counter shaft 31 on the one axial side N. Then, the electrical discharging device 6 on the one axial side N is arranged at a position where the contact member 61 can still be pushed into the back side (one axial side N) of a hole 65 in the axial direction in a state where the counter shaft 31 is moved to the one axial side N to the maximum extent. The electrical discharging device 6 on the one axial side N is arranged at a position where the contact member 61 is in contact with the end face of the counter shaft 31 even in a state where the counter shaft 31 is located closest to the other axial side T. That is, the electrical discharging device 6 on the one axial side N is arranged at a position where a biasing member 62 does not bias the contact member 61 to the maximum extent in a state where the motor shaft 22 is located closest to the other axial side T.

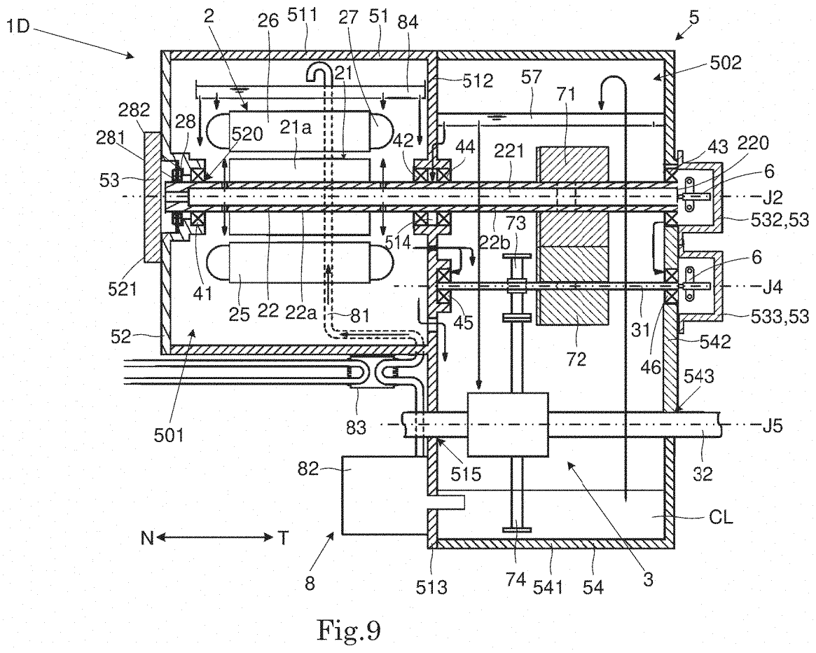

Next, a motor unit 1D according to a fifth modification will be described with reference to FIG. 9. The motor unit 1D according to the fifth modification is different from the motor unit 1 according to the embodiment in the installation position of an electrical discharging device 6. However, points other than the installation position are similar to those of the motor unit 1 according to the embodiment. For example, the configuration of the electrical discharging device 6 and the point that the electrical discharging device 6 and a contact member 61 are electrically connected to a housing 5 are common. Detailed description of the same parts is omitted unless otherwise specified. The description of the embodiment is incorporated in the description omitted.

FIG. 9 is a diagram illustrating an example of the motor unit 1D according to the fifth modification. As illustrated in the fifth modification, a reduction gear 3 includes a counter shaft 31 including a second helical gear 72 that meshes with a first helical gear 71. The electrical discharging device 6 is provided at a position where an end face on the other axial side T of the counter shaft 31 is in contact with the contact member 61. Bearings that sufficiently withstand axial force (thrust) are used for a fifth bearing 45 and a sixth bearing 46 that support the counter shaft 31. In other words, the electrical discharging device 6 may be provided on the other axial side T of the end face on the other axial side T of the counter shaft 31.

Note that as a cover member 53, a third cover member 533 that covers the electrical discharging device 6 provided on the other axial side T of the counter shaft 31 may be provided. In this case, the cover member 53 (third cover member 533) covers the electrical discharging device 6 from the outside of the housing 5 in the axial direction. The third cover member 533 accommodates the electrical discharging device 6 in the housing 5. The electrical discharging device 6 may be connected and fixed to the third cover member 533. The third cover member 533 is fixed to a second housing 54. The electrical discharging device 6 is electrically connected to the housing 5.

It is possible to remove electric charge accumulated in the counter shaft 31 that rotates by being driven by the motor shaft 22. Specifically, electric charge of the counter shaft 31 can be removed at the end part on the other axial side T. Further, even when the contact member 61 is brought into contact with the end face close to the second helical gear 72 and susceptible to the movement of the counter shaft 31, the electrical discharging device 6 can cope with the pushing force of the counter shaft 31 due to the movement in the axial direction.

On the other axial side T, the movement width of the counter shaft 31 in the axial direction during rotation can be measured in advance. In the electrical discharging device 6 on the other axial side T, a maximum stroke amount L1 of the contact member 61 in the axial direction is larger than the measured movement width of the counter shaft 31 on the other axial side T. Then, the electrical discharging device 6 on the other axial side T is arranged at a position where the contact member 61 can still be pushed into the back side (other axial side T) of a hole 65 in the axial direction in a state where the counter shaft 31 is moved to the other axial side T to the maximum extent. The electrical discharging device 6 on the other axial side T is arranged at a position where the contact member 61 is in contact with the end face of the counter shaft 31 even in a state where the counter shaft 31 is located closest to the one axial side N. That is, the electrical discharging device 6 on the other axial side T is arranged at a position where the biasing member 62 does not bias the contact member 61 to the maximum extent in a state where the motor shaft 22 is located closest to the one axial side N.

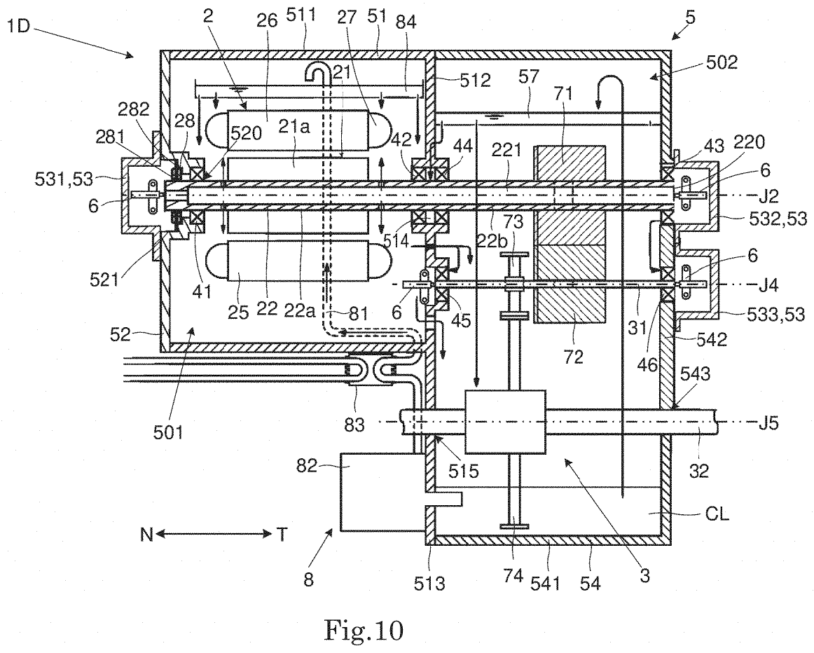

Next, a motor unit 1E according to a sixth modification will be described with reference to FIG. 10. The motor unit 1E according to the sixth modification is different from the motor unit 1 according to the embodiment in the installation position of an electrical discharging device 6. However, points other than the installation position are similar to those of the motor unit 1 according to the embodiment. For example, the configuration of the electrical discharging device 6 and the point that the electrical discharging device 6 and a contact member 61 are electrically connected to a housing 5 are common. Detailed description of the same parts is omitted unless otherwise specified. The description of the embodiment is incorporated in the description omitted.

FIG. 10 is a diagram illustrating an example of the motor unit 1E according to the sixth modification. As illustrated in the sixth modification, the reduction gear 3 includes a counter shaft 31 including a second helical gear 72 that meshes with a first helical gear 71. Then, the shaft in contact with the electrical discharging device 6 (contact member 61) may be the counter shaft 31. Note that bearings that sufficiently withstand axial force (thrust) are used for a fifth bearing 45 and a sixth bearing 46 that support the counter shaft 31. Then, a plurality of electrical discharging devices 6 may be provided. One electrical discharging device 6 may be provided at a position where the contact member 61 is in contact with an end face on one axial side N of the counter shaft 31. Further, another electrical discharging device 6 may be provided at a position where the contact member 61 is in contact with an end face on the other axial side T of the counter shaft 31. In other words, a first electrical discharging device 6 may be provided on the one axial side N of the end face on the one axial side N of the counter shaft 31. Additionally, a second electrical discharging device 6 may be provided on the other axial side T of the end face on the other axial side T of the counter shaft 31.

Note that as a cover member 53, a third cover member 533 that covers the electrical discharging device 6 provided on the other axial side T of the counter shaft 31 may be provided. In this case, the cover member 53 (third cover member 533) covers the electrical discharging device 6 from the outside of the housing 5 in the axial direction. The third cover member 533 accommodates the electrical discharging device 6 in the housing 5. The electrical discharging device 6 may be connected and fixed to the third cover member 533. The third cover member 533 is fixed to a second housing 54. The electrical discharging device 6 is electrically connected to the housing 5.

The electrical discharging device 6 can be provided at both axial ends of the counter shaft 31. Electric charge accumulated in the counter shaft 31 can be efficiently removed. Discharge at the bearing in contact with the counter shaft 31 can be reduced as much as possible.

On the one axial side N, the movement width of the counter shaft 31 in the axial direction during rotation can be measured in advance. In the electrical discharging device 6 on the one axial side N, a maximum stroke amount L1 of the contact member 61 in the axial direction is larger than the measured movement width of the counter shaft 31 on the one axial side N. The electrical discharging device 6 on the one axial side N is arranged at a position where the contact member 61 can still be pushed into the back side (one axial side N) of a hole 65 in the axial direction in a state where the counter shaft 31 is moved to the one axial side N to the maximum extent. The electrical discharging device 6 on the one axial side N is arranged at a position where the contact member 61 is in contact with the end face of the counter shaft 31 even in a state where the counter shaft 31 is located closest to the other axial side T. That is, the electrical discharging device 6 on the one axial side N is arranged at a position where a biasing member 62 does not bias the contact member 61 to the maximum extent in a state where the counter shaft 31 is located closest to the other axial side T.

On the other axial side T, the movement width of the counter shaft 31 in the axial direction during rotation can be measured in advance. In the electrical discharging device 6 on the other axial side T, a maximum stroke amount L1 of the contact member 61 in the axial direction is larger than the measured movement width of the counter shaft 31 on the other axial side T. The electrical discharging device 6 on the other axial side T is arranged at a position where the contact member 61 can still be pushed into the back side (other axial side T) of the hole 65 in the axial direction in a state where the counter shaft 31 is moved to the other axial side T to the maximum extent. The electrical discharging device 6 on the other axial side T is arranged at a position where the contact member 61 is in contact with the end face of the counter shaft 31 even in a state where the counter shaft 31 is located closest to the one axial side N. That is, the electrical discharging device 6 on the other axial side T is arranged at a position where the biasing member 62 does not bias the contact member 61 to the maximum extent in a state where the counter shaft 31 is located closest to the one axial side N.

In the fourth to sixth modifications, an electrical discharging device 6 in contact with a motor shaft 22 may be provided (see FIGS. 8 to 10). That is, the electrical discharging device 6 may be provided in each of the motor shaft 22 and the counter shaft 31. In the fourth to sixth modifications, the electrical discharging device 6 may be provided only on at least one of the end face on one side and the end face on the other side of the motor shaft 22, or the electrical discharging device 6 may be provided on both of the end faces.

As illustrated in FIG. 8 (fourth modification), a first electrical discharging device 6 may be provided at a position in contact with the end face on the one axial side N of the motor shaft 22, and a second electrical discharging device 6 may be provided at a position in contact with the end face on the one axial side N of the counter shaft 31. That is, for each of the plurality of shafts including the helical gear, one electrical discharging device 6 may be arranged at a position in contact with the end face on the one axial side N of the shaft. The axial width of the motor unit 1 can be reduced as compared with a case where the electrical discharging device 6 is arranged on both the one axial side N and the other axial side T of the shaft.

As illustrated in FIG. 9 (fifth modification), a first electrical discharging device 6 may be provided at a position in contact with the end face on the other axial side T of the motor shaft 22, and a second electrical discharging device 6 may be provided at a position in contact with the end face on the other axial side T of the counter shaft 31. That is, for each of the plurality of shafts including the helical gear, one electrical discharging device 6 may be arranged at a position in contact with the end face on the other axial side T of the shaft. The axial width of the motor unit 1 can be reduced as compared with a case where the electrical discharging device 6 is arranged on both the one axial side N and the other axial side T of the shaft.

While an embodiment of the present invention and modifications thereof have been described above, the configuration described in the embodiment and combinations thereof are merely examples, and addition, elimination, substitution of configuration(s), and other modifications can be made without departing from the scope and spirit of the present invention. Also note that the present invention is not limited by the embodiment.

The motor unit of the present invention can be used as a motor unit for driving a vehicle, for example.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A motor unit comprising:
a rotor;
a motor shaft that is attached to the rotor and rotates, and to which a first helical gear is fixed;
a stator covering a radially outer side of the rotor;
a reduction gear located on an other axial side of the motor shaft; and
an electrical discharging device including a contact member, a biasing member, and a case, wherein
the case accommodates the contact member and the biasing member;
the biasing member biases the contact member toward an end face of an end part of the motor shaft in a direction parallel to an axial direction of the motor shaft;
the contact member has conductivity, and comes into contact with the end face by biasing of the biasing member; and
a maximum stroke amount of the contact member in the axial direction is larger than a movement width of the shaft in the axial direction during rotation.

2. The motor unit according to claim 1, wherein
the case has a recessed cross section parallel to the axial direction, and includes a hole extending in the axial direction;
the biasing member is arranged on a back side of the hole; and
the contact member is arranged on an opening side of the hole.

3. The motor unit according to claim 1 further comprising a housing including a first housing that accommodates the stator and the rotor, a second housing that is located on the other axial side of the first housing and accommodates the reduction gear, and a cover member, wherein
the cover member covers the electrical discharging device from an outside of the housing in the axial direction, and accommodates the electrical discharging device in the housing.

4. The motor unit according to claim 3, wherein
the electrical discharging device is connected and fixed to the cover member.

5. The motor unit according to claim 1, wherein
the contact member is in contact with the end face on one axial side of the motor shaft.

6. The motor unit according to claim 1, wherein
the contact member is in contact with the end face on the other axial side of the motor shaft.

7. The motor unit according to claim 1, wherein
the electrical discharging device is provided at a position where the contact member is in contact with one of the end face on one axial side of the motor shaft and the end face on the other axial side of the motor shaft, the end face having a smaller movement width in the axial direction during rotation.

8. The motor unit according to claim 1, wherein
one electrical discharging device is provided at a position where the contact member is in contact with the end face on one axial side of the motor shaft, and
another electrical discharging device is provided at a position where the contact member is in contact with the end face on the other axial side of the motor shaft.

9. The motor unit according to claim 1, wherein
the reduction gear includes a counter shaft including a second helical gear meshing with the first helical gear, and
the electrical discharging device is provided at a position where the contact member is in contact with the end face on one axial side of the counter shaft.

10. The motor unit according to claim 1, wherein
the reduction gear includes a counter shaft including a second helical gear meshing with the first helical gear, and
the electrical discharging device is provided at a position where the contact member is in contact with the end face on the other axial side of the counter shaft.

11. The motor unit according to claim 1, wherein
the reduction gear includes a counter shaft including a second helical gear meshing with the first helical gear,
one electrical discharging device is provided at a position where the contact member is in contact with the end face on one axial side of the counter shaft, and
another electrical discharging device is provided at a position where the contact member is in contact with the end face on the other axial side of the counter shaft.

12. The motor unit according to claim 1, wherein
the motor shaft is a shaft in which a first shaft and a second shaft are connected in the axial direction.
